(19) United States
(12) Patent Application Publication
(10) Pub. No.: US 2009/0014847 A1
(43) Pub. Date: Jan. 15, 2009

(54) INTEGRATED CIRCUIT PACKAGE STRUCTURE WITH ELECTROMAGNETIC INTERFERENCE SHIELDING STRUCTURE

(75) Inventors: Jung-Tai Chen, Hsinchu (TW); Chun-Hsun Chu, Hsinchu (TW); Wood-Hi Cheng, Hsinchu (TW)

Correspondence Address: Workman Nydegger;1000 Eagle Gate Tower, 60 East South Temple, Salt Lake City, UT, 84111, US

(73) Assignee: INDUSTRIAL TECHNOLOGY RESEARCH INSTITUTE, Hsinchu (TW)

(21) Appl. No.: 11/968,982

(22) Filed: Jan. 3, 2008

(30) Foreign Application Priority Data
Jul. 13, 2007 (TW) 096125754

(51) Int. Cl. H01L 23/552

(52) U.S. Cl. 257/659; 257/E23.114

(57) ABSTRACT

An integrated circuit (IC) package structure with an electromagnetic interference (EMI) shielding structure utilizes double-layer successive cladding process. A dielectric coating layer and an EMI shielding layer material are sequentially coated on surface of a carrying substrate, an IC on the carrying substrate, and all the other devices. The EMI shielding layer is closely adhered to and bonded on a ground metal area exposed on an upper surface of the carrying substrate, the EMI shielding layer on the package is connected to a ground plane under the carrying substrate in series, so as to form a protection cover having a closed EMI shielding space to isolate the interference of electromagnetic waves from outside.

### CROSS-REFERENCE TO RELATED APPLICATIONS

This non-provisional application claims priority under 35 U.S.C. § 119(a) on Patent Application No(s). 096125754 filed in Taiwan, R.O.C. on Jul. 13, 2007, the entire contents of which are hereby incorporated by reference.

### BACKGROUND OF THE INVENTION

1. Field of Invention

The present invention relates to an integrated circuit (IC) package structure. More particularly, the present invention relates to an IC package structure with an electromagnetic interference (EMI) shielding structure.

2. Related Art

The demand for micro-electro-mechanical microphones has grown for use in IC device products having microphones. For example, currently, global microphone manufactures usually add a microphone for the photography function in addition to the microphone used for talking, so as to facilitate the convenient use. The micro-electro-mechanical microphones having advantages of thin thickness and small volume may be subjected to a surface-mount process through solder reflow, thus effectively reducing the assembly cost. Therefore, to meet requirements of mobile phones on small volume and low cost, the micro-electro-mechanical microphone gradually occupies the market of electric condenser microphone (ECM). In addition, the micro-electro-mechanical microphone has the inherent advantage of low power consumption (160 μA), which is only ⅓ of that of that of the ECM. For the application in the mobile phones having the limited battery capacity, the advantage of power saving is helpful to promote the micro-electro-mechanical microphone to replace the ECM.

The EMI shielding design is always a core design project in the semiconductor industry, so a considerable number of patents have been proposed on this design. For example, in U.S. Pat. No. 6,867,480, the prior art of the present invention (as shown in FIG. 1), a coating material layer 12 with electrically conductive and EMI shielding capabilities firstly clads or totally covers an IC device 10 and an electrical interconnection 11. Then, a molding transfer is performed to cover the devices on the substrate 14 with a non-electrically conductive plastic compound material 13, so as to provide protection function. U.S. Pat. No. 5,371,404, the prior art of the present invention, is directed to the IC device in flip-chip form protected by an underfill adhesive, in which the molding transfer process is performed to cover the carrying substrate and all the devices on the carrying substrate with a plastic compound material filled with electric conductive particles, so as to achieve the objectives of EMI shielding and high heat conductive coefficient at the same time. In order to achieve an objective of hermetic sealing package, U.S. Pat. No. 6,649,446, the prior art of the present invention, covers surface of the IC device area in the flip-chip protected by the underfill adhesive and all the carrying substrate with a non-electrically conductive composite semiconductor material by means of plating. For example, SiC, SiN, or another composite semiconductor material is covered on the surfaces of the above devices. Finally, the molding transfer is performed to cover all the devices with the non-electrically conductive plastic compound material to provide protection function.

Among the above patents, U.S. Pat. No. 6,649,446 is quite suitable for a flip-chip bonding package, but is not suitable for a wire bonding package. U.S. Pat. No. 5,371,404 is only applicable to the flip-chip bonding package, and the packaging plastic protection material is electrically conductive, which is liable to adversely affect peripheral devices. In U.S. Pat. No. 6,867,480, although the plastic protection layer is not electrically conductive, the electrical interconnection contacts of the semiconductor device is not provided with the structure providing electrical isolation protection, for example wire bonding interconnection mechanism of the semiconductor chip.

### SUMMARY OF THE INVENTION

Accordingly, the present invention is directed to provide a form applicable to both the wire bonding and the package bonding at the same time, and using a manner of double-layer successive cladding of a dielectric coating layer and an EMI shielding layer to form an entire protection layer of protection cover on a package structure.

The technical means provided by the present invention is to provide an IC package structure with an EMI shielding structure. The IC package structure includes a carrying substrate having an upper surface with a plurality of pads and a plurality of exposed ground metal areas thereon, an IC device disposed on the carrying substrate and electrically bonded with the pads of the carrying substrate, a dielectric coating layer coated on the IC device, the electrical bonding area, and the carrying substrate but exposing the ground metal areas of the carrying substrate, and an EMI shielding layer coated on the dielectric coating layer and the ground metal areas of the carrying substrate.

The present invention adopts the manner of double-layer successive cladding to form a dielectric layer (i.e. insulation cladding layer) and an EMI shielding layer respectively and sequentially on the carrying substrate and all the devices on the carrying substrate. The EMI shielding protection layer is adhered and bonded to the metal ground area exposed on the upper surface of the carrying substrate, such that the entire protection cover is connected to a ground plane below the carrying substrate in series through the EMI shielding protection layer on the protection cover, so as to form a complete a closed EMI shielding space. In addition to produce the electrical isolation protection function on the electrical bonding part of the semiconductor device, the interference of electromagnetic wave from outside is totally isolated.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 shows an EMI shielding package structure;

FIG. 2 is a schematic cross-sectional structural view of surface coating according to an embodiment of the IC package structure with an EMI shielding structure of the present invention;

FIG. 3 is a schematic cross-sectional structural view of an embodiment with an additional plastic protection layer of FIG. 2;

FIG. 4 is a schematic cross-sectional structural view of total coating according to an embodiment of the IC package structure with an EMI shielding structure of the present invention;

FIG. 5 is a schematic cross-sectional structural view of an embodiment with an additional plastic protection layer of FIG. 4; and

FIG. 6 shows an embodiment of the IC package structure with an EMI shielding structure in combination with a plurality of semiconductor devices.

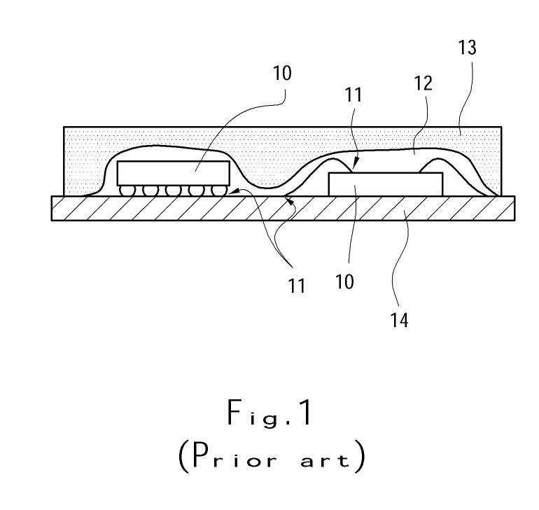

### DETAILED DESCRIPTION OF THE INVENTION

The preferred embodiments of the present invention are described in detail below in accompanying with the drawings.

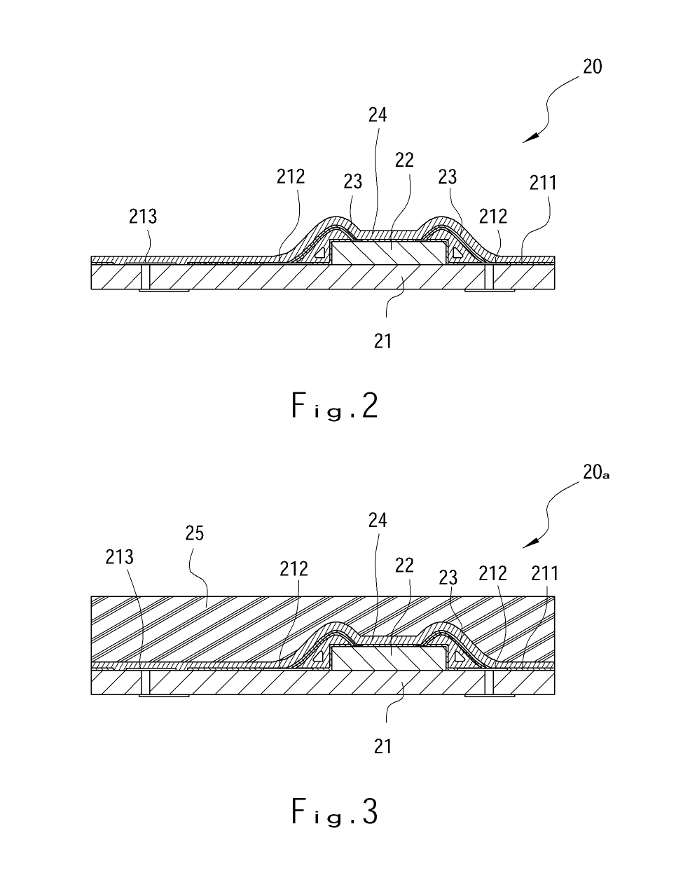

Referring to FIG. 2, a schematic cross-sectional structural view of surface coating according to an embodiment of the IC package structure with an EMI shielding structure of the present invention is shown. The IC package structure 20 includes a carrying substrate 21 having an upper surface 211 with a plurality of pads 212 and a plurality of exposed ground metal areas 213, an IC device 22 disposed on the carrying substrate 21 and electrically coupled with at least one pad 212 of the carrying substrate 21, a dielectric coating layer 23 coated on surface of the IC device 22, the electrical bonding area, and the carrying substrate 21 but exposing the ground metal areas 213 of the carrying substrate 21, and an EMI shielding layer 24 coated on the dielectric coating layer 23 and the ground metal areas 213 of the carrying substrate 21. A protection film (not shown) may be used before the dielectric coating layer 23 is coated so as to shield the ground metal areas 213, and is removed after the dielectric coating layer 23 is formed, so that the dielectric coating layer 23 may directly contact the ground metal areas 213 in subsequent processes.

Referring to FIG. 3, a schematic cross-sectional structural view of an embodiment with an additional plastic protection layer of FIG. 2 is shown. A plastic protection layer 25 may be coated on the periphery of the IC device 22, the carrying substrate 21, and the EMI shielding layer 24 in the embodiment of FIG. 2, so as to form a package with protection function.

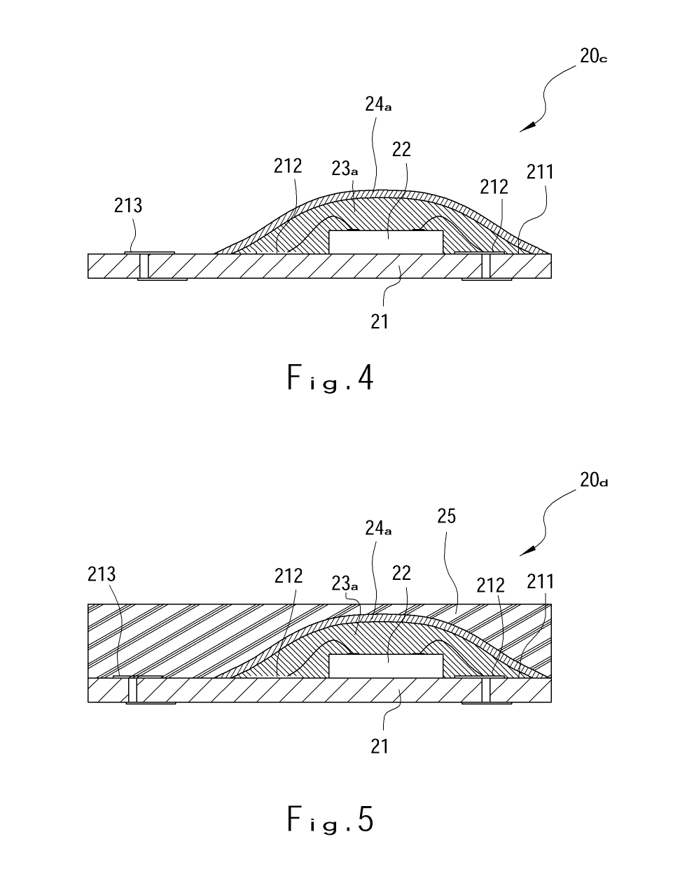

Referring to FIG. 4, a schematic cross-sectional structural view of total coating according to an embodiment of the IC package structure with an EMI shielding structure of the present invention is shown. The IC package structure includes a carrying substrate 21 having an upper surface 211 with a plurality of pads 212 and a plurality of exposed ground metal areas 213, an IC device 22 disposed on the carrying substrate 21 and electrically coupled with at least one pad 212 of the carrying substrate 21, a dielectric coating layer 23 totally covering the IC device 22, the electrical bonding area, and the carrying substrate 21, and an EMI shielding layer 24 coated on the dielectric coating layer 23 and the ground metal areas 213 of the carrying substrate 21 but exposing the ground metal areas 213 of the carrying substrate 21.

FIG. 5 is a schematic cross-sectional structural view of an embodiment with an additional plastic protection layer of FIG. 4. In FIG. 5, a plastic protection layer 25 may be coated on the periphery of the IC device 22, the carrying substrate 21, and the EMI shielding layer 24 in the above embodiment, so as to form a package having protection function.

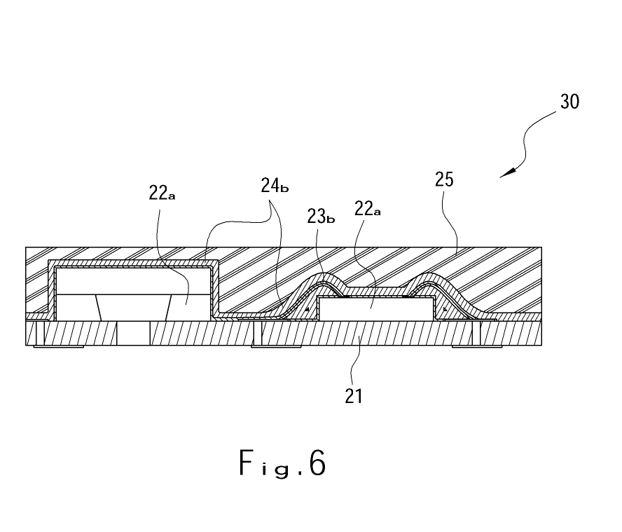

Definitely, in the above embodiments, the IC device 22 can be a micro-electro-mechanical device or an application specific integrated circuit (ASIC), and the electrical bonding manner is flip-chip bonding or wire bonding. In addition, referring to FIG. 6, an embodiment of the IC package structure with an EMI shielding structure in combination with a plurality of semiconductor devices is shown. In the above embodiments, the IC device 22 on the carrying substrate 21 of the IC package structure 30 may also be combined with an IC device 22a with another function. For example, one is an ASIC, and another is a micro-electro-mechanical device. Then, based on the above principle, a dielectric coating layer 23b and an EMI shielding layer 24b on the surface of the dielectric coating layer 23b are added on the IC device. Further, a plastic protection layer 25 is fabricated on the outer surface of EMI shielding layer 24b, so as to totally coat and protect the above all.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An integrated circuit (IC) package structure with an electromagnetic interference (EMI) shielding structure, comprising:
a carrying substrate, having an upper surface with a plurality of pads and a plurality of exposed ground metal areas;
an IC device, disposed on the carrying substrate and electrically bonded with at least one pad of the carrying substrate;
a dielectric coating layer, coated on surface of the IC device, an electrical bonding area, and the carrying substrate, but exposing the ground metal areas of the carrying substrate; and
an EMI shielding layer, coated on the dielectric coating layer and the ground metal areas of the carrying substrate.

2. The IC package structure with an EMI shielding structure as claimed in claim 1, further comprising a plastic protection layer coated on the EMI shielding layer.

3. The IC package structure with an EMI shielding structure as claimed in claim 1, wherein the electrically bonding manner of the IC device is flip-chip bonding or wire bonding.

4. The IC package structure with an EMI shielding structure as claimed in claim 3, wherein the IC device is a micro-electro-mechanical device or an application specific integrated circuit (ASIC).

5. An IC package structure with an EMI shielding structure, comprising:
a carrying substrate, having an upper surface with a plurality of pads and a plurality of exposed ground metal areas;
an IC device, disposed on the carrying substrate and electrically bonded with at least one pad of the carrying substrate;
a dielectric coating layer, totally covering the IC device, an electrical bonding area, and the carrying substrate, but exposing the ground metal areas of the carrying substrate; and
an EMI shielding layer, coated on the dielectric coating layer and the ground metal areas of the carrying substrate.

6. The IC package structure with an EMI shielding structure as claimed in claim 5, further comprising a plastic protection layer coated on the EMI shielding layer.

7. The IC package structure with an EMI shielding structure as claimed in claim 5, wherein the electrically bonding manner of the IC device is flip-chip bonding or wire bonding.

8. The IC package structure with an EMI shielding structure as claimed in claim 5, wherein the IC device is a micro-electro-mechanical device or an application specific integrated circuit (ASIC).
